(19) United States
(12) Patent Application Publication
(10) Pub. No.: US 2024/0155916 A1
(43) Pub. Date: May 9, 2024

(54) DISPLAY DEVICE AND MANUFACTURING METHOD THEREOF

(71) Applicant: Wuhan China Star Optoelectronics Semiconductor Display Technology Co., Ltd., Wuhan Hubei (CN)

(72) Inventors: Cuilin ZHU, Wuhan, Hubei (CN); Qingliang LI, Wuhan, Hubei (CN); Yanqiang DUAN, Wuhan, Hubei (CN); Congcong JIANG, Wuhan, Hubei (CN)

(73) Assignee: Wuhan China Star Optoelectronics Semiconductor Display Technology Co., Ltd., Wuhan, Hubei (CN)

(21) Appl. No.: 17/418,267

(22) PCT Filed: Apr. 25, 2021
(86) PCT No.: PCT/CN2021/089656

§ 371 Date: Jun. 25, 2021

(30) Foreign Application Priority Data
Apr. 14, 2021 (CN) 202110402354.9

(51) Int. Cl. H10K 59/80; H04N 23/55; H04N 23/90; H10K 59/65

(52) U.S. Cl. CPC H10K 59/872; H04N 23/55; H04N 23/90; H10K 59/65; H10K 59/8791; H10K 59/8794

(57) ABSTRACT

The present application provides a display device and a manufacturing method thereof. The display device includes a display module and a cover plate on the display module. The display module includes a display region including a flat display region and a plurality of curved display regions adjacent to the flat display region and extending in different directions, a non-display region including a plurality of corner regions between adjacent ones of the curved display regions, and a functional device provided in at least one of the plurality of the corner regions to increase a screen-to-body ratio of the display device.

### FIELD OF INVENTION

The present application relates to a field of display technology and more particularly to a display device and a manufacturing method thereof.

### BACKGROUND OF INVENTION

In the display industry, a demand of market for products such as mobile phones, TVs, tablets, notebooks, and digital cameras is increasing. Display screens used in these products are gradually developing towards full screens. For flexible displays, a production of four-curved screen that can display all four sides has gradually become a trend of research and development of next-generation display technology. However, a screen-to-body ratio of the current four-curved screen is still low and needs to be improved.

### SUMMARY OF INVENTION

The present application provides a display device and a manufacturing method thereof to solve a problem of low screen-to-body ratio of the current four-curved screen.

In a first aspect, the present application provides a display device, including a display module and a cover plate positioned on the display module, wherein the display module includes:
a display region comprising a flat display region and a plurality of curved display regions adjacent to the flat display region and extending in different directions;
a non-display region comprising a plurality of corner regions between adjacent ones of the curved display regions; and
a functional device provided in at least one of the plurality of the corner regions.

In some embodiments, the display device further including a frame, wherein the display module is attached to the frame; and
an ink layer positioned on a side of the cover plate close to the frame in the corner regions, wherein the ink layer is provided with a through-hole, wherein the functional device is disposed between the ink layer and the frame and opposite to the through-hole.

In some embodiments, the functional device includes a housing and a functional element, and wherein the functional element is provided opposite to the through-hole.

In some embodiments, the functional device includes one or a combination of a camera, an infrared sensor, an earpiece, or a flash.

In some embodiments, a number of the curved display regions is four, and the four curved display regions respectively extend in an upper, a lower, a left, and a right directions of the flat display region.

In some embodiments, the functional device is a periscope camera, and the periscope camera includes a lens and a camera, and wherein the lens and the camera are respectively arranged at different ones of the plurality of corner regions.

In some embodiments, the four curved display regions form four of the corner regions, and each one of the four corner regions is provided with one of the cameras respectively.

In some embodiments, the frame is a rectangular parallelepiped structure with rounded corners, and the frame comprises a front surface, a rear surface, an upper surface, a lower surface, a left surface, and a right surface, and wherein the flat display region is attached to the front surface, the plurality of the curved display regions are respectively a first curved display region, a second curved display region, a third curved display region, and a fourth curved display region, the first curved display region is attached to the upper surface, the second curved display region is attached to the lower surface, the third curved display region is attached to the left surface, and the fourth curved display region is attached to the right surface.

In some embodiments, the display module in the display region includes:
an array transistor layer;
a light-emitting device layer disposed on the array transistor layer; and
an encapsulation layer disposed on the light-emitting device layer; and
wherein the cover plate is disposed on the encapsulation layer.

In some embodiments, the display module in the display region further includes a heat dissipation layer and a back plate disposed on the heat dissipation layer, and wherein the array transistor layer is disposed on the back plate, a polarizer is disposed between the light-emitting device layer and the encapsulation layer, and the cover plate and the encapsulation layer are connected by an optical glue.

In a second aspect, a method of manufacturing a display device, including steps of:
providing a display module and a cover plate, wherein the display module includes a display region including a flat display region and a plurality of curved display regions adjacent to the flat display region and extending in different directions, and a non-display region including a plurality of corner regions between adjacent ones of the curved display regions;
attaching the cover plate to the display module and providing a functional device in at least one of the plurality of the corner regions.

In some embodiments, before the step of attaching the cover plate to the display module and providing the functional device in at least one of the plurality of the corner regions further includes:
providing a frame and attaching the display module to the frame;
disposing an ink layer with a through-hole positioned on a side of the cover plate close to the frame in the corner region to dispose the functional device between the ink layer and the frame and opposite to the through-hole.

In some embodiments, the functional device includes a housing and a functional element, and the step of disposing the functional device between the ink layer and the frame and opposite to the through-hole further includes:
disposing the functional element opposite to the through-hole.

In some embodiments, the functional device includes one or a combination of a camera, an infrared sensor, an earpiece, or a flash.

In some embodiments, a number of the curved display regions is four, and the four curved display regions respectively extend in an upper, a lower, a left, and a right directions of the flat display region.

In some embodiments, the functional device is a periscope camera, and the periscope camera includes a lens and a camera, and wherein the lens and the camera are respectively arranged at different ones of the plurality of corner regions.

In some embodiments, the four curved display regions form four of the corner regions, and each one of the four corner regions is provided with one of the cameras respectively.

In some embodiments, the frame is a rectangular parallelepiped structure with rounded corners, and the frame includes a front surface, a rear surface, an upper surface, a lower surface, a left surface, and a right surface, and wherein the flat display region is attached to the front surface, the plurality of the curved display regions are respectively a first curved display region, a second curved display region, a third curved display region, and a fourth curved display region, the first curved display region is attached to the upper surface, the second curved display region is attached to the lower surface, the third curved display region is attached to the left surface, and the fourth curved display region is attached to the right surface.

In some embodiments, the display module in the display region includes:
an array transistor layer;
a light-emitting device layer disposed on the array transistor layer; and
an encapsulation layer disposed on the light-emitting device layer; and
wherein the cover plate is disposed on the encapsulation layer.

In some embodiments, the display module in the display region further includes a heat dissipation layer and a back plate disposed on the heat dissipation layer, and wherein the array transistor layer is disposed on the back plate, a polarizer is disposed between the light-emitting device layer and the encapsulation layer, and the cover plate and the encapsulation layer are connected by an optical glue.

The display device provided by the present application includes a cover plate and a display module attached to the cover plate. The display device includes a display module and a cover plate positioned on the display module. The display module includes a display region including a flat display region and a plurality of curved display regions adjacent to the flat display region and extending in different directions, a non-display region including a plurality of corner regions between adjacent ones of the curved display regions, and a functional device provided in at least one of the plurality of the corner regions. Since at least one corner region is provided with functional device such as a camera, an infrared sensor, an earpiece, or a flash, therefore, compared with the design in the prior art where the functional device is arranged in the flat display region, the display device provided by the present application effectively utilizes the corner region that did not originally display, and by disposing these functional devices in the corner region, the screen-to-body ratio of the display device is improved.

### DESCRIPTION OF FIGURES

FIG. 1 is a schematic diagram of a structure of a four-curved screen in the prior art.

FIG. 2 is a schematic structural diagram of a display device provided by one embodiment of the present application.

FIG. 3 is a schematic structural diagram of a frame provided by one embodiment of the present application.

FIG. 4 is a schematic structural diagram of a display module provided by one embodiment of the present application.

FIG. 5 is a schematic structural diagram of a display device provided by another embodiment of the present application.

FIG. 6 is a partial cross-sectional view of the display device shown in FIG. 2 along a line I-I.

FIG. 7 is a partial cross-sectional view of the display device shown in FIG. 2 along a line II-II.

FIG. 8 is a flowchart of a method of manufacturing the display device provided by the embodiment of the present application.

### DETAILED DESCRIPTION OF EMBODIMENTS

In order to make the purpose, technical solutions, and effects of the present application more specific and clearer, the following further describes the present application in detail with reference to the figures and embodiments. It should be understood that the specific embodiments described here are only used to explain the present application, and are not used to limit the present application.

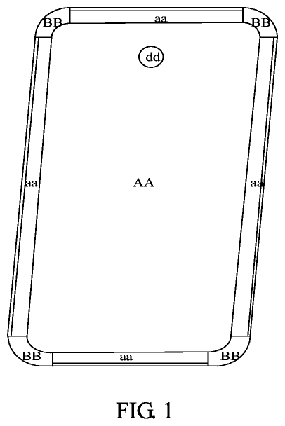

Please refer to FIG. 1, the current four-curved screen includes a flat display region AA and four curved display regions aa connected to the flat display region AA. The flat display region AA is positioned on a front of the four-curved screen, and the four curved display regions aa are respectively positioned on the four sides of the four-curved screen. The flat display region AA is usually provided with functional devices such as a camera dd, which makes the flat display region AA unable to truly achieve full-screen display, and there are also a plurality of corner regions BB that cannot display between the two adjacent curved display regions aa. In summary, the screen-to-body ratio of the current four-curved screen still needs to be improved. In order to solve the above technical problems, the embodiment of the present application provides a new display device, which will be described in detail below.

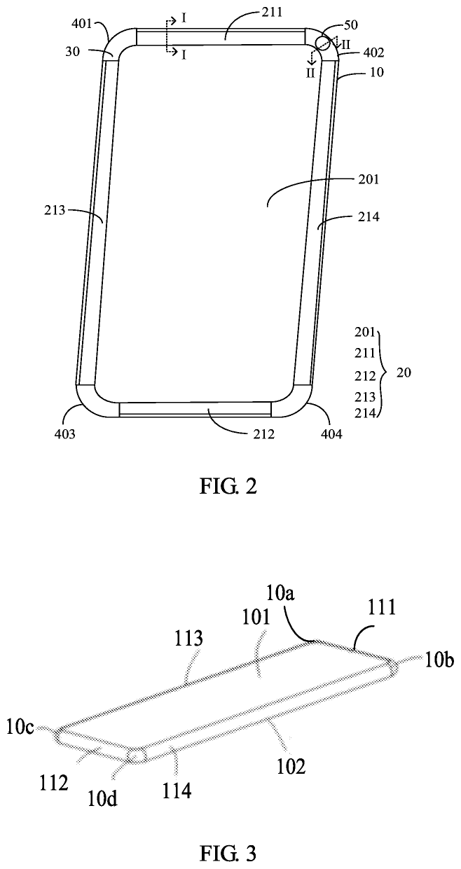

Please refer to FIG. 2, the embodiment of the present application provides a display device. The display device may be a product with display function such as a mobile phone, a TV, a tablet, a notebook, or a digital camera. The display device includes a display module 20 and a cover plate 30 positioned on the display module 20. Preferably, the display module 20 can be attached to a frame 10. The frame 10, the display module 20, and the cover plate 30 will be described in detail below.

An outer surface of the frame 10 is configured to support the display module 20, so that the display module 20 and the entire display device have better strength. An accommodating space may also be formed inside the frame 10, and the accommodating space is configured to accommodate accessories such as mainboards and batteries related to the display module 20, so as to prevent the accessories from being damaged by external impact.

In the embodiment of the present application, please refer to FIG. 3, the frame is a rectangular parallelepiped structure with rounded corners. The frame 10 includes six surface including a front surface 101, a rear surface 102, an upper surface 111, a lower surface 112, a left surface 113, and a right surface 114, wherein the front surface 101 and the rear surface 102 are both flat surfaces, and the upper surface 111, the lower surface 112, the left surface 113, and the right surface 114 are all curved surfaces, and the left surface 113, the lower surface 112, the right surface 114 and the upper surface 111 are connected end to end, forming a Gaussian region where the two surfaces are connected. It should be noted that the Gaussian region refers to an area with has non-single bending directions, that is, an area with multiple bending directions. For example, a spherical surface is a typical Gaussian region. In the embodiment of the present application, an overlapping position of two or more curved surfaces forms a Gaussian region. Specifically, the upper surface 111 and the left surface 113 form a first Gaussian region 10a, the upper surface 111 and the right surface 114 form a second Gaussian region 10b, the lower surface 112 and the left surface 113 form a third Gaussian region 10c, and the lower surface 112 and the right surface 114 form a fourth Gaussian region 10d.

The display module 20 can be an organic light-emitting diode (OLED) display module, a quantum dot light emitting diodes (QLED) display module, or a mini light-emitting diode (mini-LED) display module or micro light-emitting diode (micro-LED) display modules, etc., which are not specifically limited in the embodiment of the present application.

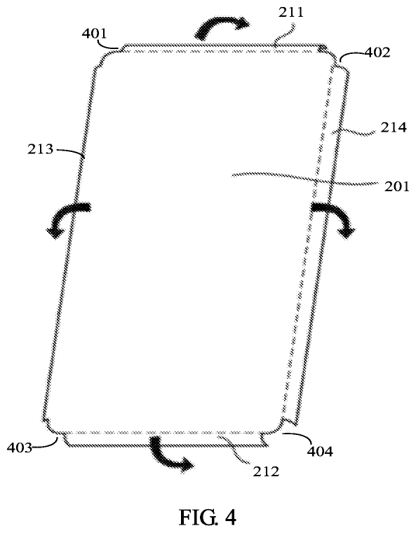

Please refer to FIG. 4, the display module 20 includes a display region and a non-display region. The display region includes a flat display region 201 and a plurality of curved display regions adjacent to the flat display region 201 and extending in different directions. In the embodiment of the present application, there are four curved display regions, and the four curved display regions are a first curved display region 211, a second curved display region 212, a third curved display region 213, and a fourth curved display region 214, wherein the flat display region 201 is attached to the front surface 101 of the frame 10, the first curved display region 211 extends upwards along the flat display region 201 and is attached to the upper surface 111 of the frame 10, the second curved display region 212 extends downwards along the flat display region 201 and is attached to the lower surface 112 of the frame 10, the third curved display region 213 extends to the left along the flat display region 201 and is attached to the left surface 113 of the frame 10, and the fourth curved display region 214 extends to the right along the flat display region 201 and is attached to the right surface 114 of the frame 10.

The non-display region includes a plurality of corner regions between adjacent ones of the curved display regions. In the embodiment of the present application, a first corner region 401 is formed between the first curved display region 211 and the third curved display region 213, wherein the first corner region 401 exposes the first Gaussian region 10a; a second corner region 402 is formed between the first curved display region 211 and the fourth curved display region 214, wherein the second corner region 402 exposes the second Gaussian region 10b; a third corner region 403 is formed between the second curved display region 212 and the third curved display region 213, wherein third corner region 403 exposes the third Gaussian region 10c; and a fourth corner region 404 is formed between the second curved display region 212 and the fourth curved display region, wherein the fourth corner region 404 exposes the fourth Gaussian region 10d.

At least one corner region is provided with a functional device 50. In the embodiment of the present application, a functional device is provided in at least one of the first corner region 401, the second corner region 402, the third corner region 403, or the fourth corner region 404. It should be noted that the functional device 50 includes one or a combination of a camera, an infrared sensor, an earpiece, or a flash, wherein the functional device 50 can also be other devices that provide specific functions for the display device, and there is no specific limitation in the embodiment of the present application. For example, in the display device shown in FIG. 2, only the second corner region 402 is provided with a camera. It should be noted that the camera can be a normal camera or a wide-angle camera. If the second corner region 402 does not have enough space to install an entire camera module, the lens and the camera in the entire camera module can be separated. For example, if a periscope camera module is adopted a lens of the periscope camera module can be installed in the second corner region 402, and a camera of the periscope camera module can be installed in other regions such as the other corner regions which have enough space to accommodate the camera of the periscope camera module and do not affect the display. It is understandable that in the embodiment of the present application, the lens and the camera of the camera module are separately arranged in different corner regions, so that a reasonable layout of the camera module can be realized, preventing a problem that the camera module cannot be installed in the same corner region due to space constraints.

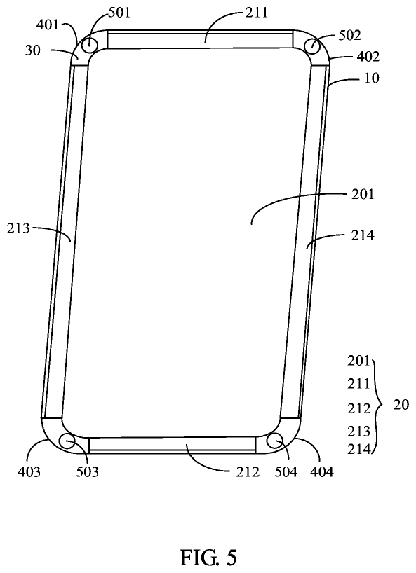

For another example, in the display device shown in FIG. 5, the first corner region 401 is provided with a first camera 501, the second corner region 402 is provided with a second camera 502, the third corner region 403 is provided with a third camera 503, and the fourth corner region 404 is provided with a fourth camera 504. The four cameras described above are controlled to work together through an algorithm to realize real-time photography and video recording in 720° full space and ultra-wide-angle real-time photography and video recording, and combined with augmented reality (AR) or virtual reality (VR), to realize three dimensional (3D) real-time photography and video recording, and multi-angle and multi-directional of real-time accurate photography and video recording without adjusting the position of the product.

The display device provided by the embodiment of the present application includes a display module 20 and a cover plate 30 on the display module 20. The display module 20 includes a display region including a flat display region 201 and a plurality of curved display regions adjacent to the flat display region 201 and extending in different directions, and a non-display region including a plurality of corner regions between adjacent ones of the curved display regions. Since at least one corner region is provided with a functional device 50 such as a camera, an infrared sensor, an earpiece, or a flashlight, therefore, compared with the design in the prior art where the functional device 50 is arranged in the flat display region 201, the display device provided by the embodiment of the present application effectively utilizes the corner region that did not originally display, and by disposing these functional devices 50 in the corner region, the screen-to-body ratio of the display device is improved.

It should be noted that, in the embodiment of the present application, the frame 10 is selected as a rectangular parallelepiped structure with rounded corners to describe the display device. At this time, the display device is roughly in a shape of the rectangular parallelepiped. In other embodiments, the frame 10 may also be shapes of structures such as triangular prisms with rounded corners or N (N>4) prisms with rounded corners. At this time, the shape of the display device also changes accordingly, which is such as triangular prisms or N (N>4) prisms.

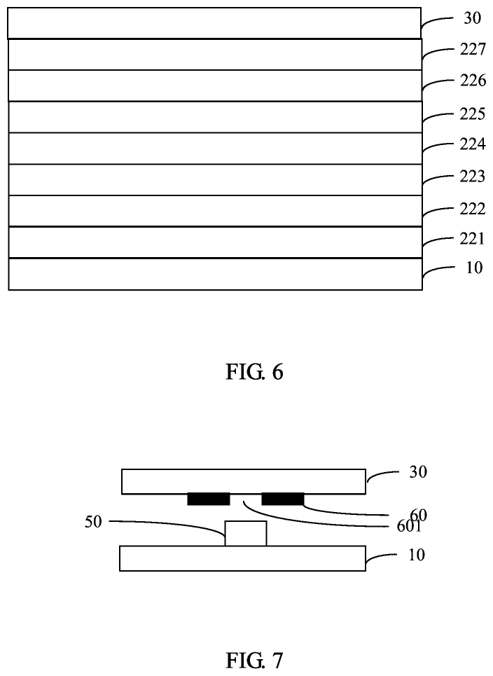

In some embodiments of the present application, please refer to FIG. 6, the display module 20 in the display region may include a heat dissipation layer 221 disposed on the frame 10, a back plate 222 disposed on the heat dissipation layer 221, and an array transistor layer 223 disposed on the back plate 222, a light-emitting device layer 224 disposed on the array transistor layer 223, an encapsulation layer 225 disposed on the light-emitting device layer 224, a polarizer 226 disposed on the encapsulation layer 225, and an optical glue 227 disposed on the polarizer 226, wherein the cover plate 30 is connected to the polarizer 226 through the optical glue 227.

Specifically, the heat dissipation layer 221 has good thermal conductivity, can quickly dissipate the heat generated by the light-emitting device layer 224 when it is lit, and improves a service life of the light-emitting device layer 224. In the embodiment of the present application, the heat dissipation layer 221 is not in direct contact with the light-emitting device layer 224. At this time, a material of the heat dissipation layer 221 may be an insulator heat dissipation material, a semiconductor heat dissipation material, or a metal material. In other embodiments of the present application, if the heat dissipation layer 221 is in direct contact with the light-emitting device layer 224, then the heat dissipation layer 221 is made of an insulator heat dissipation material or a semiconductor heat dissipation material. It should be noted that the insulator heat dissipation material includes aluminum nitride (AlNx), boron nitride (BN), polycrystalline boron nitride (PBN), or aluminum oxide (Al₂O₃), and the metal material is aluminum (Al), magnesium (Mg) or copper (Cu). In the embodiment of the present application, the heat dissipation layer 221 is made of aluminum oxide (AlNx). Since the aluminum oxide (AlNx) has good thermal conductivity, the heat dissipation layer 221 made of aluminum oxide (AlNx) will significantly improve the heat dissipation of the light-emitting device layer 224, thereby greatly prolonging the service life of the light-emitting device layer 224. In other embodiments of the present application, the heat dissipation layer 221 may also be two or three layers, etc. The multiple layers of heat dissipation layers 221 are stacked, and the materials of the multiple layers of heat dissipation layers 221 may be the same or different. In specific implementations, the number and material of the heat dissipation layer 221 are not specifically limited in the embodiment of the present application, and can be selected based on heat dissipation requirements. The heat dissipation layer 221 can be prepared by a chemical vapor deposition (CVD) process, an atomic layer deposition (ALD) process, or a physical vapor deposition (PVD) process, which is not specifically limited in the embodiment of the present application.

The back plate 222 is configured to support and protect the flexible light-emitting device layer 224 to prevent the light-emitting device layer 224 from being damaged by external impact. In the embodiment of the present application, a material of the back plate 222 may be polyethylene terephthalate (PET) material. Because PET material has the advantages of low elastic modulus and not easy to expand when heated, the back plate 222 made of PET material will not be deformed due to changes in ambient temperature, which reduces the possibility of peeling of the film layer connected to the back plate 222, thereby improving the product yield and reliability of the display.

The array transistor layer 223 is configured to drive the light-emitting device layer 224 to emit light, and the array transistor layer 223 includes a plurality of thin film transistors (TFTs) arranged in an array.

The light-emitting device layer 224 is configured to emit light. The light-emitting device layer 224 usually includes an anode disposed on the array transistor layer 223, a hole injection layer (HIL) disposed on the anode, a hole transport layer (HTL) disposed on the hole injection layer, an emission layer (EML) disposed on the hole transport layer, an electron transport layer (ETL) disposed on the light-emitting layer, an electron injection layer (EIL) disposed on the electron transport layer, and a cathode disposed on the electron injection layer. Optionally, the light-emitting device layer 224 may also be provided with a hole blocking layer (HBL), an electron blocking layer (EBL), and a capping layer (CPL).

The encapsulation layer 225 is configured to isolate external water and oxygen to ensure a product yield of the display module 20. The encapsulation layer 225 is usually a sandwich structure composed of an organic layer, an inorganic layer, and an organic layer.

The polarizer 226 is configured to eliminate the reflected light obtained by reflecting the incident light by the metal electrode in the display device, thereby improving a contrast of the display device.

The optical glue 227 is configured to bond optical components. The optical glue 227 has the advantages of colorlessness and transparency, a light transmittance above 90%, a good bonding strength, curability at room temperature or medium temperature, and small curing shrinkage. In the embodiment of the present application, the optical glue 227 is configured to glue the polarizer 226 and the cover plate 30.

The cover plate 30 is configured to protect the light-emitting device layer 224 and the like from external impact force and to decorate an appearance of the display device. In other embodiments of the present application, a touch layer may also be integrated in the display device, and in this case, the user can interact with the display device by touching the cover plate 30.

In some embodiments of the present application, please refer to FIG. 7, an ink layer 60 is disposed on a side of the cover plate 30 close to the frame 10 in the corner regions, wherein the ink layer 60 is provided with a through-hole 601, and the functional device 50 is disposed between the ink layer 60 and the frame 10 and opposite to the through-hole 601, wherein the functional device 50 can be directly mounted on the frame and the functional device 50 and the frame 10 are fixedly connected. The embodiment of the present application does not specifically limit the connection relationship between the functional device 50 and the frame 10. In the embodiment of the present application, the functional device 50 is taken as an example of a camera for description, by disposing the ink layer 60 with a through-hole 601 on a side of the cover plate 30 close to the frame 10, and the camera is disposed between the ink layer 60 and the frame 10 and opposite to the through-hole 601, so that it can ensure that an ambient light is transmitted from the through-hole 601 to the camera for taking pictures and videos, and a purity of the ambient light transmitted to the camera can be ensured. In addition, the ink layer 60 can also achieve a black-out design of the corner region except for the functional device 50 to decorate an appearance of the display device.

In some embodiments of the present application, the functional device 50 includes a housing and a functional element, and the functional element is disposed opposite to the through-hole 601. The embodiment of the present application takes the functional device 50 as an example of a camera for description. At this time, the functional element is a lens, and the housing is arranged around the periphery of the lens. The ink layer 60 is preferably an annular region surrounded by an outer ring and an inner ring. The lens is disposed opposite to the through-hole 601 surrounded by the inner ring, and the housing is disposed opposite to the annular region. Therefore, not only can pure ambient light transmitted from the through-hole 601 to the camera for taking pictures and videos be ensured, but the ring-shaped ink layer 60 can also be used to shield the housing, improving aesthetics of the display device.

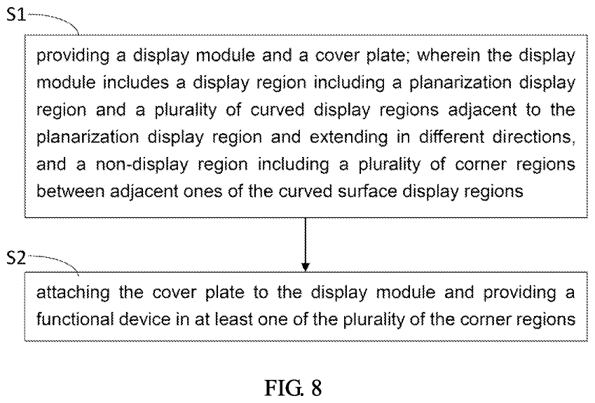

Please refer to FIG. 8, the embodiment of the present application provides a method of manufacturing the display device. It should be noted that the display device manufactured by the method of manufacturing the display device is shown in FIGS. 2 to 7, wherein the display device may be a product with display function such as a mobile phone, a TV, a tablet, a notebook, or a digital camera, and the method of manufacturing the display device includes the steps of:

Step S1, providing a display module 20 and a cover plate 30; wherein the display module 20 includes a display region including a flat display region 201 and a plurality of curved display regions adjacent to the flat display region 201 and extending in different directions, and a non-display region including a plurality of corner regions between adjacent ones of the curved display regions.

Step S2, attaching the cover plate 30 to the display module 20 and providing a functional device 50 in at least one of the plurality of the corner regions.

It should be noted that before step S1, the display module 20 can be attached to the frame 10 first.

An outer surface of the frame 10 is configured to support the display module 20, so that the display module 20 and an entire display device have better strength. An accommodating space may also be formed inside the frame 10, and the accommodating space is configured to accommodate accessories such as mainboards and batteries related to the display module 20, so as to prevent the accessories from being damaged by external impact.

In this embodiment of the present application, please refer to FIG. 3, the frame 10 is a rectangular parallelepiped structure with rounded corners. The frame 10 includes six surface including a front surface 101, a rear surface 102, an upper surface 111, a lower surface 112, a left surface 113, and a right surface 114, wherein the front surface 101 and the rear surface 102 are both flat surfaces, and the upper surface 111, the lower surface 112, the left surface 113, and the right surface 114 are all curved surfaces, and the left surface 113, the lower surface 112, the right surface 114 and the upper surface 111 are connected end to end, forming a Gaussian region where the two surface are connected. It should be noted that the Gaussian region refers to an area with has non-single bending directions, that is, an area with multiple bending directions. For example, a spherical surface is a typical Gaussian region. In the embodiment of the present application, an overlapping position of two or more curved surfaces intersect forms a Gaussian region. Specifically, the upper surface 111 and the left surface 113 form a first Gaussian region 10a, the upper surface 111 and the right surface 114 form a second Gaussian region 10b, the lower surface 112 and the left surface 113 form a third Gaussian region 10c, and the lower surface 112 and the right surface 114 form a fourth Gaussian region 10d.

The display module 20 can be an organic light-emitting diode (OLED) display module, a quantum dot light emitting diodes (QLED) display module, or a mini light-emitting diode (mini-LED) display module or micro light-emitting diode (micro-LED) display modules, etc., which are not specifically limited in the embodiments of the present application.

Please refer to FIG. 4, the display module 20 includes a display region and a non-display region. The display region includes a flat display region 201 and a plurality of curved display regions adjacent to the flat display region 201 and extending in different directions. In the embodiment of the present application, there are four curved display regions, and the four curved display regions are a first curved display region 211, a second curved display region 212, a third curved display region 213, and a fourth curved display region 214, wherein the flat display region 201 is attached to the front surface 101 of the frame 10, the first curved display region 211 extends upwards along the flat display region 201 and is attached to the upper surface 111 of the frame 10, the second curved display region 212 extends downwards along the flat display region 201 and is attached to the lower surface 112 of the frame 10, the third curved display region 213 extends to the left along the flat display region 201 and is attached to the left surface 113 of the frame 10, and the fourth curved display region 214 extends to the right along the flat display region 201 and is attached to the right surface 114 of the frame 10.

The non-display region includes a plurality of corner regions between adjacent ones of the curved display regions. In the embodiment of the present application, a first corner region 401 is formed between the first curved display region 211 and the third curved display region 213, wherein the first corner region 401 exposes the first Gaussian region 10a; a second corner region 402 is formed between the first curved display region 211 and the fourth curved display region 214, wherein the second corner region 402 exposes the second Gaussian region 10b; a third corner region 403 is formed between the second curved display region 212 and the third curved display region 213, wherein third corner region 403 exposes the third Gaussian region 10c; and a fourth corner region 404 is formed between the second curved display region 212 and the fourth curved display region, wherein the fourth corner region 404 exposes the fourth Gaussian region 10d.

At least one corner region is provided with a functional device 50. In the embodiment of the present application, a functional device is provided in at least one of the first corner region 401, the second corner region 402, the third corner region 403, or the fourth corner region 404. It should be noted that the functional device 50 includes one or a combination of a camera, an infrared sensor, an earpiece, or a flash, wherein the functional device 50 can also be other devices that provide specific functions for the display device, there is no specific limitation in the embodiment of the present application. For example, in the display device shown in FIG. 2, only the second corner region 402 is provided with a camera. It should be noted that the camera can be a normal camera or a wide-angle camera. If the second corner region 402 does not have enough space to install an entire camera module, the lens and the camera in the entire camera module can be separated. For example, if a periscope camera module is adopted, only a lens of the periscope camera module can be installed in the second corner region 402, and a camera of the periscope camera module can be installed in other regions such as the other corner regions which have enough space to accommodate the camera of the periscope camera module and do not affect the display. For another example, in the display device shown in FIG. 5, the first corner region 401 is provided with a first camera 501, the second corner region 402 is provided with a second camera 502, the third corner region 403 is provided with a third camera 503, and the fourth corner region 404 is provided with a fourth camera 504. The four cameras described above are controlled to work together through an algorithm to realize real-time photography and video recording in 720° full space and ultra-wide-angle real-time photography and video recording, and combined with augmented reality (AR) or virtual reality (VR) to realize three dimensional (3D) real-time photography and video recording, and multi-angle and multi-directional of real-time accurate photography and video recording without adjusting the position of the product.

The display device manufactured by the method of manufacturing the display device provided by the embodiment of the present application includes a display module and a cover plate 30 on the display module 20. The display module 20 includes a display region including a flat display region 201 and a plurality of curved display regions adjacent to the flat display region 201 and extending in different directions, a non-display region including a plurality of corner regions between adjacent ones of the curved display regions. Since at least one corner region is provided with functional device 50 such as a camera, an infrared sensor, an earpiece, or a flashlight, therefore, compared with the design in the prior art where the functional device 50 is arranged in the flat display region 201, the embodiment of the present application effectively utilizes the corner region that did not originally display, and by disposing these functional devices 50 in the corner region, the screen-to-body ratio of the display device is improved.

In some embodiments, before the step of attaching the cover plate 30 to the display module 20 and providing the functional device 50 in at least one of the plurality of the corner regions further includes:

Providing a frame 10 and attaching the display module 20 to the frame 10.

Disposing an ink layer 60 with a through-hole 601 positioned on a side of the cover plate 30 close to the frame 10 in the corner region to dispose the functional device 50 between the ink layer 60 and the frame 10 and opposite to the through-hole 601, wherein the functional device 50 can be directly mounted on the frame 10 and the functional device 50 and the frame 10 are fixedly connected. This embodiment of the present application does not specifically limit the connection relationship between the functional device 50 and the frame 10.

Specifically, in the embodiment of the present application, the functional device 50 takes an example of a camera for description. By disposing the ink layer 60 with a through-hole 601 on a side of the cover plate 30 close to the frame 10, and disposing the camera between the ink layer 60 and the frame 10 and opposite to the through-hole 601, it can be ensured that an ambient light is transmitted from the through-hole 601 to the camera for taking pictures and videos, and a purity of the ambient light transmitted to the camera can be ensured. In addition, the ink layer 60 can also achieve a black-out design of the corner region except for the functional device 50 to decorate an appearance of the display device.

In some embodiments, the functional device 50 includes a housing and a functional element, and the functional element is disposed opposite to the through-hole 601; accordingly, the step of disposing the functional device 50 on a side of the ink layer 60 away from the cover plate 30 and opposite to the through-hole 601 includes: disposing the functional element opposite to the through-hole 601.

The embodiment of the present application takes the functional device 50 as a camera for description. At this time, the functional element is a lens, and the housing is arranged around the periphery of the lens. The ink layer 60 is preferably an annular region surrounded by an outer ring and an inner ring. The lens is disposed opposite to the through-hole 601 surrounded by the inner ring, and the housing is disposed opposite to the annular region. Therefore, not only can pure ambient light transmitted from the through-hole 601 to the camera for taking pictures and videos be ensured, but the ring-shaped ink layer 60 can also be used to shield the housing, improving aesthetics of the display device.

It can be understood that for those of ordinary skill in the art, equivalent substitutions or changes can be made according to the technical solutions and concept of the present application, and all these changes or substitutions shall fall within a protection scope of the appended claims of the present application.

What is claimed is:

1. A display device, comprising a display module and a cover plate positioned on the display module, wherein the display module comprises:
a display region comprising a flat display region and a plurality of curved display regions adjacent to the flat display region and extending in different directions;
a non-display region comprising a plurality of corner regions between adjacent ones of the curved display regions; and
a functional device provided in at least one of the plurality of the corner regions.

2. The display device according to claim 1, further comprising:
a frame, wherein the display module is attached to the frame; and
an ink layer disposed on a side of the cover plate close to the frame in the corner regions, wherein the ink layer is provided with a through-hole, and the functional device is disposed between the ink layer and the frame and opposite to the through-hole.

3. The display device according to claim 2, wherein the functional device comprises a housing and a functional element, and the functional element is provided opposite to the through-hole.

4. The display device according to claim 1, wherein the functional device comprises one or a combination of a camera, an infrared sensor, an earpiece, or a flash.

5. The display device according to claim 1, wherein a number of the curved display regions is four, and the four curved display regions respectively extend in an upper, a lower, a left, and a right direction of the flat display region.

6. The display device according to claim 5, wherein the functional device is a periscope camera, and the periscope camera comprises a lens and a camera, and wherein the lens and the camera are respectively arranged at different ones of the plurality of corner regions.

7. The display device according to claim 5, wherein the four curved display regions form four of the corner regions, and each one of the four corner regions is provided with one camera, respectively.

8. The display device according to claim 2, wherein the frame is a rectangular parallelepiped structure with rounded corners, and the frame comprises a front surface, a rear surface, an upper surface, a lower surface, a left surface, and a right surface, and wherein the flat display region is attached to the front surface, the plurality of the curved display regions are respectively a first curved display region, a second curved display region, a third curved display region, and a fourth curved display region, the first curved display region is attached to the upper surface, the second curved display region is attached to the lower surface, the third curved display region is attached to the left surface, and the fourth curved display region is attached to the right surface.

9. The display device according to claim 1, wherein the display module in the display region comprises:
an array transistor layer;
a light-emitting device layer disposed on the array transistor layer; and
an encapsulation layer disposed on the light-emitting device layer;
wherein the cover plate is disposed on the encapsulation layer.

10. The display device according to claim 9, wherein the display module in the display region further comprises a heat dissipation layer and a back plate disposed on the heat dissipation layer, the array transistor layer is disposed on the back plate, a polarizer is disposed between the light-emitting device layer and the encapsulation layer, and the cover plate and the encapsulation layer are connected by an optical glue.

11. A method of manufacturing a display device, comprising steps of:
providing a display module and a cover plate, wherein the display module comprises a display region comprising a flat display region and a plurality of curved display regions adjacent to the flat display region and extending in different directions, and a non-display region comprising a plurality of corner regions between adjacent ones of the curved display regions; and
attaching the cover plate to the display module and providing a functional device in at least one of the plurality of the corner regions.

12. The method of manufacturing the display device according to claim 11, wherein before the step of attaching the cover plate to the display module and providing the functional device in at least one of the plurality of the corner regions further comprises:
providing a frame and attaching the display module to the frame; and
disposing an ink layer with a through-hole positioned on a side of the cover plate close to the frame in the corner region to dispose the functional device between the ink layer and the frame and opposite to the through-hole.

13. The method of manufacturing the display device according to claim 12, wherein the functional device comprises a housing and a functional element, and the step of disposing the functional device between the ink layer and the frame and opposite to the through-hole further comprises:
disposing the functional element opposite to the through-hole.

14. The method of manufacturing the display device according to claim 11, wherein the functional device comprises one or a combination of a camera, an infrared sensor, an earpiece, or a flash.

15. The method of manufacturing the display device according to claim 11, wherein a number of the curved display regions is four, and the four curved display regions respectively extend in an upper, a lower, a left, and a right direction of the flat display region.

16. The method of manufacturing the display device according to claim 15, wherein the functional device is a periscope camera, and the periscope camera comprises a lens and a camera, and wherein the lens and the camera are respectively arranged at different ones of the plurality of corner regions.

17. The method of manufacturing the display device according to claim 15, wherein the four curved display regions form four of the corner regions, and each one of the four corner regions is provided with one camera, respectively.

18. The method of manufacturing the display device according to claim 12, wherein the frame is a rectangular parallelepiped structure with rounded corners, and the frame comprises a front surface, a rear surface, an upper surface, a lower surface, a left surface, and a right surface, and wherein the flat display region is attached to the front surface, the plurality of the curved display regions are respectively a first curved display region, a second curved display region, a third curved display region, and a fourth curved display region, the first curved display region is attached to the upper surface, the second curved display region is attached to the lower surface, the third curved display region is attached to the left surface, and the fourth curved display region is attached to the right surface.

19. The method of manufacturing the display device according to claim 11, wherein the display module in the display region comprises:
an array transistor layer;
a light-emitting device layer disposed on the array transistor layer; and
an encapsulation layer disposed on the light-emitting device layer;
wherein the cover plate is disposed on the encapsulation layer.

20. The method of manufacturing the display device according to claim 19, wherein the display module in the display region further comprises a heat dissipation layer and a back plate disposed on the heat dissipation layer, the array transistor layer is disposed on the back plate, a polarizer is disposed between the light-emitting device layer and the encapsulation layer, and the cover plate and the encapsulation layer are connected by an optical glue.
